(19) United States
(12) Patent Application Publication
(10) Pub. No.: US 2007/0007654 A1
(43) Pub. Date: Jan. 11, 2007

(54) Metal line of semiconductor device and method for forming thereof

(76) Inventor: Shim Cheon Man, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/483,306

(22) Filed: Jul. 7, 2006

(30) Foreign Application Priority Data
Jul. 8, 2005 (KR) 10-2005-0061714

(51) Int. Cl. H01L 21/4763; H01L 23/48

(52) U.S. Cl. 257/751; 438/643; 257/774; 438/637

(57) ABSTRACT

There is provided a metal line of a semiconductor device and a method for forming the metal line. In the method, a first metal line can be formed above a semiconductor substrate. An etch barrier layer can be formed on the first metal line. An interlayer insulating layer can be formed on the etch barrier layer and selectively removed to form a via hole and a trench. A portion of the interlayer insulating layer located in the via hole can be etched to expose the first metal line, and a plasma surface treatment can be performed on the interlayer insulating layer in which the via hole and the trench are formed and on the exposed first metal line by using an NH₃ plasma treatment. A metal diffusion barrier layer and a second metal line can then be formed in the trench and the via hole.

### RELATED APPLICATION

This application claims the benefit, under 35 U.S.C. §119(e), of Korean Patent Application Number 10-2005-0061714 filed Jul. 8, 2005, which is incorporated herein by reference in its entirety.

### FIELD OF THE INVENTION

The present invention relates to a metal line of a semiconductor device and a method for forming the metal line of the semiconductor device.

### BACKGROUND OF THE INVENTION

Recently, copper and copper alloys are being widely used for forming metal lines of a semiconductor device because copper and copper alloys have low specific resistances, good electro migration (EM) and stress migration (SM) characteristics, and are not expensive.

In a process for forming a metal line using copper (or a copper alloy), copper is deposited in a via hole (or a contact hole) and a trench, having a dual damascene structure, in order to simultaneously form a plug and a metal line. Then, unnecessary portions of the deposited copper are removed by chemical mechanical polishing (CMP).

However, the related art method of forming a metal line on a semiconductor device has disadvantages.

That is, single damascene or dual damascene structures with copper for the metal lines in 0.13-μm or smaller semiconductor devices.

Here, the electro migration of copper (Cu) is ten times larger than that of aluminum (Al).

In addition, an interlayer insulating layer is generally formed using a material having a lower dielectric constant instead of using SiO₂, so as to increase the speed of a semiconductor device and reduce the power consumption of the semiconductor device. However, the lower the dielectric constant the material has, the lower the density the material has.

In this case, the low dielectric constant material (the interlayer insulating layer) does not firmly bond to a metal diffusion barrier layer that is formed to prevent copper diffusion. The reason for this is that since the low dielectric constant material has hydrogen and carbon and is exposed to gas containing fluorine during an etch process, the lower dielectric constant material forms with fluorine on its surface.

Therefore, in the related art, the metal diffusion barrier layer is not firmly bonded to the interlayer insulating layer, thereby deteriorating the thermal stability and reliability of the semiconductor device.

### SUMMARY OF THE INVENTION

Accordingly, the present invention is directed to a metal line of a semiconductor device and a method for forming the metal line that addresses and/or substantially obviates one or more problems, limitations, and/or disadvantages of the related art.

An object of the present invention is to provide a metal line of a semiconductor device, in which a metal diffusion barrier layer can be firmly bonded to an interlayer insulating layer so as to improve the reliability of the semiconductor device, and a method for forming the metal line of the semiconductor device.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method for forming a metal line of a semiconductor device, the method including: forming a first metal line on a semiconductor substrate or a dielectric layer; forming an etch barrier layer on the first metal line; forming an interlayer insulating layer on the etch barrier layer; forming a via hole and a trench by selectively removing the interlayer insulating layer; exposing the first metal line by etching a portion of the interlayer insulating layer located in the via hole; performing a plasma surface treatment on the interlayer insulating layer in which the via hole and the trench are formed and on the exposed first metal line by using NH₃; and forming a metal diffusion barrier layer and a second metal line in the trench and the via hole.

In another aspect of the present invention, there is provided a metal line of a semiconductor device, the metal line incorporating: a first metal line and an etch barrier layer sequentially formed on a semiconductor substrate or a dielectric layer; an interlayer insulating layer formed above the first metal line incorporating a via hole and a trench, the interlayer insulating layer being treated by a plasma surface treatment using NH₃; and a metal diffusion barrier layer and a second metal line sequentially formed in the trench and the via hole.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A to 1F are sectional views for explaining a method for forming a metal line of a semiconductor device according to an embodiment the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

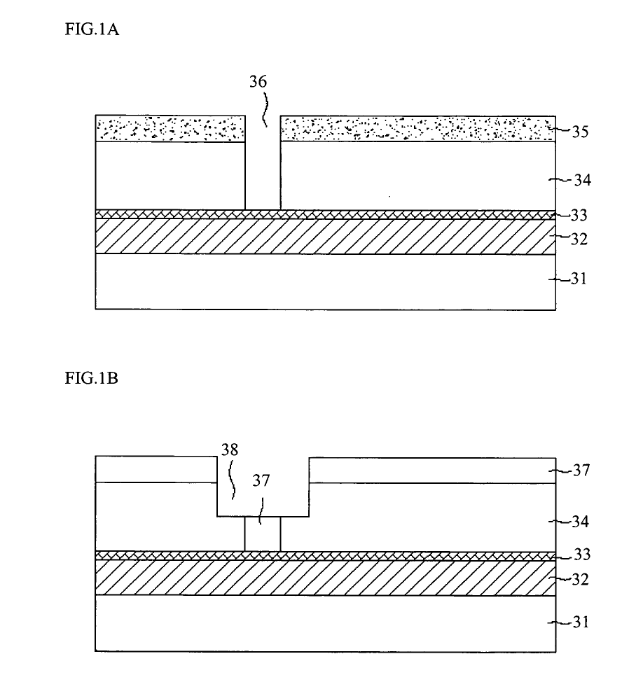

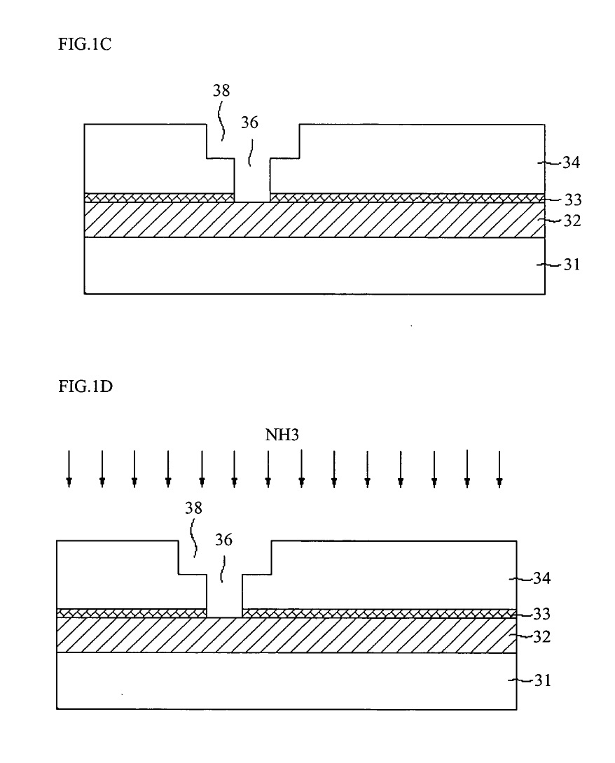

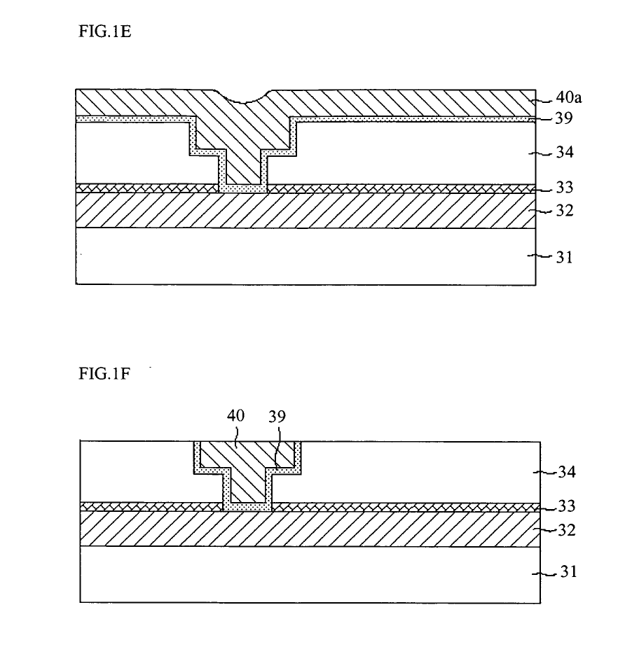

FIGS. 1A to 1F are sectional views for explaining a method for forming a metal line of a semiconductor device according to an embodiment of the present invention.

Referring to FIG. 1A, in an embodiment, a first metal line 32 can be formed by depositing a first copper thin layer above a semiconductor substrate 31, and performing photolithography and etch processes to selectively remove the first copper thin layer so as to form the first copper line 32. In one embodiment, the first copper line 32 can be formed on the semiconductor substrate 31. In another embodiment, the first copper line 32 can be formed on a dielectric layer.

Next, an etch barrier layer 33 can be formed on the entire surface of the semiconductor substrate 31 including the first copper line 32, and an interlayer insulating layer 34 can be formed on the etch barrier layer 33. In one embodiment, the etch barrier layer 33 can be formed of a nitride layer.

In a specific embodiment, the etch barrier layer 33 can function as an etch stop layer, and the interlayer insulating layer 34 can be formed of a material having a low dielectric constant (hereinafter, referred to as a low-k material) or an ultra low-k material (k<2.5).

Next, a first photoresist 35 can be formed on the interlayer insulating layer 34, and exposing and developing processes can be performed to pattern the first photoresist 35 so as to define a contact region.

Then, the interlayer insulating layer 34 can be selectively etched using the patterned first photoresist 35 as an etch mask and the etch barrier layer 33 as an etch end point, so as to form a via hole 36.

Referring to FIG. 1B, once the first photoresist 35 is removed, a second photoresist 37 can be formed all over the semiconductor substrate 31 including in the via hole 36. Exposing and developing process can be performed to pattern the second photoresist 37.

Next, the interlayer insulating layer 34 can be selectively removed to a predetermined depth by using the patterned second photoresist 37 as an etch mask, so as to form a trench 38.

Referring to FIG. 1C, the second photoresist 37 can be removed and a portion of the etch barrier layer 33 remaining in the via hole 36 can be etched away.

In one embodiment, the etch barrier layer 33 can be etched away using the second photoresist 37 or the interlayer insulating layer 34 as an etch mask.

Referring to FIG. 1D, the semiconductor substrate 31 can be plasma treated using gas containing NH₃ to remove elements, such as hydrogen, carbon, and fluorine, from the surface of the interlayer insulating layer 34. Here, the hydrogen and carbon are characteristic elements of a low-k material, and fluorine is an element that can form on the surface of the interlayer insulating layer 34 while the via hole 36 and the trench 38 are formed.

In specific embodiments, the plasma treatment can be performed on the interlayer insulating layer 34 using gas, such as NH₃ or a mixture of NH₃ and at least one of He, H₂, Ar, N₂, O₂, and CO, in order to remove unstable or poorly cohesive elements from the interlayer insulating layer 34 and attach cohesive nitrogen on the surface of the interlayer insulating layer 34. Therefore, the interlayer insulating layer 34 can be firmly coupled with a metal diffusion barrier layer 39 (refer to FIG. 1E).

When the interlayer insulating layer 34 is formed of a ultra low-k material, the interlayer insulating layer 34 has a number of pores such that the metal diffusion barrier layer 39 can permeate the interlayer insulating layer 34. In this case, the thickness of the interlayer insulating layer 34 reduces substantially, and thus capacitance increases. Therefore, the metal diffusion barrier layer 39 cannot prevent copper diffusion efficiently.

Therefore, the NH₃ plasma treatment conditions can be properly controlled to increase the surface density of the interlayer insulating layer 34 and at the same time activate the surface of the interlayer insulating layer 34 by nitrogen, so that the metal diffusion barrier layer 39 can be firmly deposited on the interlayer insulating layer 34 to a very thin thickness without permeation into the interlayer insulating layer 34. Therefore, metal resistance can be reduced, and the process can be simplified when compared with the case of depositing a sealing material that is hard to control.

In another embodiment of the present invention, the NH₃ plasma treatment can be performed before the second photoresist 37 is removed. In this case, the NH₃ plasma treatment can be performed intensively on portions of the interlayer insulating layer 34 exposed by the via hole 36 and the trench 38.

Referring to Fig. 1E, the metal diffusion barrier layer 39 can be formed above the entire surface of the semiconductor substrate 31 including the trench 38 and the via hole 36.

In one embodiment, the metal diffusion barrier layer 39 can be formed to a thickness in the range of 10 Å to 1000 Å. The metal diffusion barrier layer 39 can be formed of a conductive material. In a specific embodiment, the metal diffusion barrier layer 39 can be a material such as TiN, Ta, TaN, WNX, and TiAl(N) and formed by physical vapor deposition or chemical vapor deposition. The metal diffusion barrier layer 39 prevents diffusion of a copper thin layer (described layer), so that copper atoms cannot diffuse from the copper thin layer into the interlayer insulating layer 34.

Next, a copper seed layer can be formed on the metal diffusion barrier layer 39, and electroplating can be performed to form a second copper thin layer 40a.

Deposition of a stable and clean copper seed layer is necessary for the electroplating.

In another embodiment method, the metal diffusion barrier layer 39 and the copper seed layer can be deposited in a physical vapor deposition (PVD) chamber or a chemical vapor deposition (CVD) chamber. Then, the second copper thin layer 40a can be formed using electroplating equipment.

In embodiments, the second copper thin layer 40a can be formed by depositing copper on the copper seed layer without vacuum break by using a metal-organic chemical vapor deposition (MOCVD) or electroplating method.

In an embodiment where the copper thin layer 40a is formed by MOCVD, the depositing temperature can range from 50° C. to 300° C., and a precursor of the copper thin layer 40a can be used at 5 to 100 sccm (standard cubic centimeter per minute). In a specific embodiment, a mixture of (hfac)CuTMVS and an additive, a mixture of (hfac)CuVTMOS and an additive, or a mixture of (hfac)CuPENTENE and an additive can be used as the precursor.

In an embodiment where the copper thin layer 40a is formed by electroplating, copper can be deposited on the copper seed layer without vacuum break at a low temperature ranging from −20° C. to 150° C.

Referring to FIG. 1F, CMP can be performed on the entire surface of the second copper thin layer 40a using the interlayer insulating layer 34 as a polishing stop layer to remove the second copper thin layer 40a and the metal diffusion barrier layer 39, so as to form a second copper line 40 in the trench 38 and the via hole 36.

For embodiments of the subject invention, when the NH₃ plasma surface treatment is performed on the interlayer insulating layer 34 in a reactor using NH₃ and at least one of He, H₂, Ar, N₂, O₂, and CO, the percentage of the NH₃ can range from 0<NH₃<100.

Further, the NH₃ plasma surface treatment of the interlayer insulating layer 34 can be performed in a depositing chamber of the metal diffusion barrier layer 39 (in-situ process) or before proceeding to the depositing chamber (ex-situ process)

In an embodiment, the NH₃ plasma surface treatment of the interlayer insulating layer 34 can be performed at a remote place, and it can be performed using high-density plasma or normal-density plasma.

In one embodiment, the NH₃ plasma surface treatment of the interlayer insulating layer 34 can be performed at a temperature range of −30° C. to 400° C. In a further embodiment, the NH₃ plasma surface treatment of the interlayer insulating layer 34 can be performed in a plasma power range of 1 W to 10 KW.

As described above, the present invention can provide the following advantages.

The surface of the interlayer insulating layer can be treated using plasma containing NH₃ to remove unstable or poorly cohesive chemical groups and to attach very cohesive nitrogen, so as to improve the bonding force between the interlayer insulating layer and the metal diffusion barrier layer, and thereby to improve reliability.

Further, when the interlayer insulating layer is formed of an ultra low-k material (k<2.5), the NH₃ plasma treatment conditions can be properly adjusted to increase the surface density of interlayer insulating layer and activate the surface of the interlayer insulating layer by nitrogen, so that the metal diffusion barrier layer can be firmed formed on the interlayer insulating layer without permeation into the interlayer insulating layer.

Furthermore, the metal diffusion barrier layer can be formed to a very small thickness, so that metal resistance can be reduced and the process can be simplified when compared with the case of depositing a sealing material that is hard to control.

In addition, the metal diffusion barrier layer can be bonded to the interlayer insulating layer more firmly, and thus stripping of the metal diffusion barrier layer can be effectively prevented during CMP. Therefore, the process can be controlled more easily.

It will be apparent to those skilled in the art that various modifications and variations can be made in the present invention. Thus, it is intended that the present invention covers the modifications and variations of this invention provided they come within the scope of the appended claims and their equivalents.

I claim:

1. A method for forming a metal line of a semiconductor device, the method comprising:
forming a first metal line above a semiconductor substrate;
forming an etch barrier layer on the first metal line;
forming an interlayer insulating layer on the etch barrier layer;
forming a via hole and a trench by selectively removing the interlayer insulating layer;
exposing the first metal line by etching a portion of the interlayer insulating layer located in the via hole
performing a plasma surface treatment on the interlayer insulating layer in which the via hole and the trench are formed, and on the exposed first metal line using NH₃; and
forming a metal diffusion barrier layer and a second metal line in the trench and the via hole.

2. The method according to claim 1, wherein performing the plasma surface treatment using NH₃ further uses at least one of He, H₂, Ar, N₂, O₂, and CO.

3. The method according to claim 2, wherein the percent of the NH₃ ranges 0<NH₃<100.

4. The method according to claim 1, wherein the plasma surface treatment is an in-situ process performed in a deposition chamber for forming the metal diffusion barrier layer.

5. The method according to claim 1, wherein the plasma surface treatment is an ex-situ process performed before proceeding to a deposition chamber for forming the metal diffusion barrier layer.

6. The method according to claim 1, wherein the plasma surface treatment is performed using remote plasma or high-density plasma.

7. The method according to claim 1, wherein the plasma surface treatment is performed in a temperature range of −30° C. to 400° C.

8. The method according to claim 1, wherein the plasma surface treatment is performed in a power range of 1 W to 10 KW.

9. The method according to claim 1, wherein the plasma surface treatment removes characteristic elements of a low-k material including hydrogen and carbon from a surface of the interlayer insulating layer, and removes a fluorine group formed on the surface of the interlayer insulating layer resulting from forming the via hole and the trench are formed in the interlayer insulating layer.

10. The method according to claim 1, wherein the interlayer insulating layer is formed of a low-k material or an ultra low-k material.

11. The method according to claim 1, wherein the etch barrier layer is a nitride layer.

12. The method according to claim 1, wherein the metal diffusion barrier layer is formed of TiN, Ta, TaN, WNX, or TiAl(N) to a thickness of 10 Å to 1000 Å by PVD (physical vapor deposition) or CVD (chemical vapor deposition).

13. The method according to claim 1, wherein the second metal line is formed at a temperature ranging from 50° C. to 300° C. and at a precursor flow rate ranging from 5 sccm to 100 sccm (standard cubic centimeter per minute) by MOCVD (metal-organic chemical vapor deposition).

14. A metal line of a semiconductor device, comprising:
a first metal line and an etch barrier layer sequentially formed above a semiconductor substrate;
an interlayer insulating layer formed above the first metal line, comprising a via hole and a trench, wherein the interlayer insulating layer is treated by a plasma surface treatment using NH₃; and
a metal diffusion barrier layer and a second metal line sequentially formed in the trench and the via hole.

15. The metal line according to claim 14, wherein the plasma surface treatment is performed using NH₃ with addition of at least one of He, H₂, Ar, N₂, O₂, and CO.

16. The metal line according to claim 15, wherein the percent of the NH₃ ranges 0<NH₃<100.

17. The metal line according to claim 14, wherein the plasma surface treatment is performed to remove characteristic elements of a low-k material including hydrogen and carbon from a surface of the interlayer insulating layer, and to remove a fluorine group formed on the surface of the interlayer insulating layer resulting from the formation of the via hole and the trench in the interlayer insulating layer.

18. The metal line according to claim 14, wherein the interlayer insulating layer is formed of a low-k material or an ultra low-k material.

19. The metal line according to claim 14, wherein the etch barrier layer is a nitride layer.

20. The metal line according to claim 14, wherein the metal diffusion barrier layer is formed of TiN, Ta, TaN, WNX, or TiAl(N) to a thickness of 10 Å to 1000 Å by PVD (physical vapor deposition) or CVD (chemical vapor deposition).
